(19) United States
(12) Patent Application Publication
(10) Pub. No.: US 2024/0255565 A1
(43) Pub. Date: Aug. 1, 2024

(54) SERVICE LIFE DIAGNOSTIC DEVICE AND POWER CONVERSION DEVICE

(71) Applicant: Mitsubishi Electric Corporation, Tokyo (JP)

(72) Inventor: Yukihiko WADA, Chiyoda-ku, Tokyo (JP)

(73) Assignee: Mitsubishi Electric Corporation, Tokyo (JP)

(21) Appl. No.: 18/566,087

(22) PCT Filed: Jun. 15, 2021
(86) PCT No.: PCT/JP2021/022706

§ 371 Date: Dec. 1, 2023

(51) Int. Cl. G01R 31/26

(52) U.S. Cl. CPC G01R 31/2642

(57) ABSTRACT

A service life diagnostic device includes a Vce amplifier, a Vee amplifier, and a service life diagnostic unit. The Vce amplifier measures a voltage between a collector main terminal connected to a collector electrode of a semiconductor element mounted on a semiconductor device, and an emitter main terminal connected to an emitter electrode of the semiconductor element. The Vee amplifier measures a voltage Vee between the emitter main terminal and an emitter reference terminal connected to the emitter electrode. The service life diagnostic unit diagnoses a service life of the semiconductor device using a correlation value between a temporal change of the voltage Vce and a temporal change of the voltage Vee.

### TECHNICAL FIELD

The present disclosure relates to a service life diagnostic device and a power conversion device for a semiconductor device.

### BACKGROUND ART

Japanese Patent Laying-Open No. 2010-81796 (PTL 1) discloses a technique for diagnosing deterioration of a joint portion between an electrode of a semiconductor element inside a semiconductor module used for a semiconductor device and a terminal of the semiconductor module. In the technique, a voltage between a plurality of terminals of the semiconductor module is measured to estimate a degree of deterioration of the joint portion from a comparison result between a temporal change of the measured voltage and a predetermined diagnostic criterion, and to predict a remaining service life of the semiconductor device.

### CITATION LIST

### Patent Literature

PTL 1: Japanese Patent Laying-Open No. 2010-81796

### SUMMARY OF INVENTION

### Technical Problem

In general, even when specifications of a plurality of semiconductor modules are the same, there is an individual difference in characteristics of the plurality of semiconductor modules. Therefore, in the technique disclosed in PTL 1, when a temporal change in voltage according to a characteristic of a certain semiconductor module is used as a diagnostic criterion, there is a possibility that a remaining service life of a semiconductor device using another semiconductor module is erroneously diagnosed. That is, in the technique disclosed in PTL 1, individual differences in the characteristics of the semiconductor modules are not excluded, and thus a diagnostic accuracy of the remaining service life is low.

The present disclosure has been made to solve the above problem, and an object thereof is to provide a service life diagnostic device and a power conversion device capable of accurately diagnosing a remaining service life of a semiconductor device.

### Solution to Problem

A service life diagnostic device according to an aspect of the present disclosure diagnoses a service life of a semiconductor device. The service life diagnostic device includes a first voltage measuring instrument, a second voltage measuring instrument, and a diagnostic unit. The first voltage measuring instrument measures a first voltage between a first terminal connected to a first electrode of a semiconductor element mounted on the semiconductor device and a second terminal connected to a second electrode of the semiconductor element. The second voltage measuring instrument measures a second voltage between a second terminal and a third terminal connected to the second electrode. The service life diagnostic unit diagnoses the service life of the semiconductor device using a correlation value between a temporal change of the first voltage and a temporal change of the second voltage.

### Advantageous Effects of Invention

According to the present disclosure, the correlation value between the temporal change of the first voltage and the temporal change of the second voltage is used for service life diagnosis. The temporal change of the first voltage and the temporal change of the second voltage vary in individuals of the semiconductor modules each including the semiconductor element, the first terminal, the second terminal, and the third terminal. However, variation in a temporal change of the correlation value is small in the individuals of the semiconductor modules. Therefore, it is possible to perform the service life diagnosis with high accuracy in which influence of an individual difference of the semiconductor modules is eliminated.

### BRIEF DESCRIPTION OF THE DRAWINGS

FIG. 1 is a block diagram illustrating one example of a configuration of a service life diagnostic device according to a first embodiment of the present disclosure.

FIG. 2 is a schematic cross-sectional view illustrating one example of an internal structure of a semiconductor module.

FIG. 3 is a diagram illustrating a relationship between a degree of progress deterioration (service life consumption rate) of a semiconductor module 30A and temporal changes of voltages Vce, Vee.

FIG. 4 is a diagram illustrating a relationship between a degree of progress deterioration (service life consumption rate) of a semiconductor module 30B and temporal changes of voltages Vce, Vee.

FIG. 5 is a diagram illustrating a correlation between temporal change amounts ΔVce, ΔVee in semiconductor module 30A.

FIG. 6 is a diagram illustrating a correlation between temporal change amounts ΔVce, ΔVee in semiconductor module 30B.

FIG. 7 is a diagram illustrating an influence of slight fluctuations in values of voltages Vce, Vee.

FIG. 8 is a diagram illustrating a temporal change of a correlation value “Vee magnification/Vce magnification” calculated in a second service life diagnosis example.

FIG. 9 is a diagram illustrating a correlation between temporal change amounts ΔVce, ΔVee in semiconductor module 30A when voltages at a time point of the service life consumption rate of 30% are used as reference values.

FIG. 10 is a diagram illustrating a correlation between temporal change amounts ΔVce, ΔVee in semiconductor module 30B when voltages at the time point of the service life consumption rate of 30% are used as the reference values.

FIG. 11 is a diagram illustrating a correlation between temporal change amounts ΔVce, ΔVee in semiconductor module 30A when voltages at a time point of the service life consumption rate of 40% are used as the reference values.

FIG. 12 is a diagram illustrating a correlation between temporal change amounts ΔVce, ΔVee in semiconductor module 30B when voltages at the time point of the service life consumption rate of 40% are used as the reference values.

FIG. 13 is a diagram illustrating a correlation between temporal change amounts ΔVce, ΔVee in semiconductor module 30A when voltages at a time point of the service life consumption rate of 50% are used as the reference values.

FIG. 14 is a diagram illustrating a correlation between temporal change amounts ΔVce, ΔVee in semiconductor module 30B when voltages at the time point of the service life consumption rate of 50% are used as the reference values.

FIG. 15 is a diagram illustrating the correlation between temporal change amounts ΔVce, ΔVee in semiconductor module 30A when voltages at a time point of the service life consumption rate of 60% are used as the reference values.

FIG. 16 is a diagram illustrating a correlation between temporal change amounts ΔVce, ΔVee in semiconductor module 30B when voltages at the time point of the service life consumption rate of 60% are used as the reference values.

FIG. 17 is a block diagram illustrating one example of a configuration of a service life diagnostic device according to a third embodiment of the present disclosure.

FIG. 18 is a block diagram illustrating a configuration of a power conversion system to which a power conversion device according to a fourth embodiment of the present disclosure is applied.

### DESCRIPTION OF EMBODIMENTS

Hereinafter, referring to the drawings, embodiments of the present disclosure will be described in detail. Note that in figures, the same or corresponding units and portions are denoted by the same reference signs, and description thereof will not be repeated. In the following figures, a relationship between sizes of components may be different from an actual relationship.

### First Embodiment

### (Overall Configuration of Service Life Diagnostic Device)

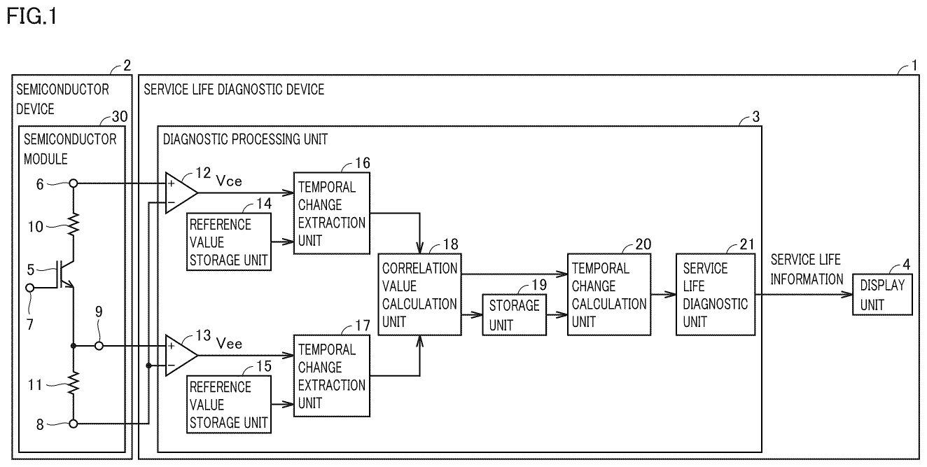

FIG. 1 is a block diagram illustrating one example of a configuration of a service life diagnostic device according to a first embodiment of the present disclosure. A service life diagnostic device 1 is connected to a semiconductor device 2 and diagnoses a service life of semiconductor device 2. Specifically, service life diagnostic device 1 diagnoses the service life of semiconductor device 2 by diagnosing a deterioration state of an electrical joint point in a semiconductor module 30 inside semiconductor device 2.

Semiconductor module 30 includes a semiconductor element 5. Semiconductor element 5 is, for example, an insulated-gate bipolar transistor (IGBT), a metal-oxide-semiconductor field-effect transistor (MOSFET), or another semiconductor element. Hereinafter, semiconductor element 5 that is an IGBT will be described. Semiconductor element 5 has a collector electrode, an emitter electrode, and a gate electrode. Semiconductor module 30 has a collector main terminal 6, a gate terminal 7, an emitter main terminal 8, and an emitter reference terminal 9 as terminals connected to electrodes of semiconductor element 5. Collector main terminal 6 is connected to a collector electrode of semiconductor element 5 via a collector-side main circuit connecting portion 10 such as a metal wire, a metal ribbon, or a metal plate. Emitter main terminal 8 is connected to an emitter electrode of semiconductor element 5 via an emitter-side main circuit connecting portion 11 such as a metal wire, a metal ribbon, or a metal plate. Gate terminal 7 is connected to a gate terminal of semiconductor element 5. Emitter reference terminal 9 is connected to the emitter electrode of semiconductor element 5.

Semiconductor element 5 is driven to be in either an ON state in which a large current flows from collector main terminal 6 to emitter main terminal 8 or an OFF state in which no current flows from collector main terminal 6 to emitter main terminal 8. The ON state and the OFF state are switched in accordance with whether or not a positive or negative voltage is applied between gate terminal 7 and emitter reference terminal 9. Note that a large current does not flow between gate terminal 7 and emitter reference terminal 9.

In semiconductor element 5, the large current is intermittently applied from collector main terminal 6 to emitter main terminal 8. Therefore, deterioration is likely to occur in collector-side main circuit connecting portion 10 and emitter-side main circuit connecting portion 11. On the other hand, since a large current does not flow through gate terminal 7 and emitter reference terminal 9, deterioration hardly occurs in these connection portions. Therefore, service lives of collector-side main circuit connecting portion 10 and emitter-side main circuit connecting portion 11 are selected as diagnosis targets.

As illustrated in FIG. 1, service life diagnostic device 1 includes a diagnostic processing unit 3 and a display unit 4. Diagnostic processing unit 3 diagnoses deterioration states of collector-side main circuit connecting portion 10 and emitter-side main circuit connecting portion 11 to diagnose the service life of semiconductor device 2. Diagnostic processing unit 3 displays a diagnosis result on display unit 4. Display unit 4 is, for example, a liquid crystal display. Display unit 4 may be present outside service life diagnostic device 1.

Diagnostic processing unit 3 is configured of, for example, software executed on an arithmetic device such as a microcomputer or a central processing unit (CPU), hardware such as a circuit device to implement various functions, and the like.

Diagnostic processing unit 3 is configured of a Vce amplifier 12, a Vee amplifier 13, reference value storage units 14, 15, temporal change extraction units 16, 17, a correlation value calculation unit 18, a storage unit 19, a temporal change calculation unit 20, and a service life diagnostic unit 21.

Vce amplifier 12 measures a voltage between collector main terminal 6 and emitter main terminal 8, and amplifies a measurement result to a voltage Vce suitable for post-processing. Vce amplifier 12 outputs voltage Vce to temporal change extraction unit 16.

Vee amplifier 13 measures a voltage between emitter reference terminal 9 and emitter main terminal 8, and amplifies a measurement result to a voltage Vee suitable for post-processing. Vee amplifier 13 outputs voltage Vee to temporal change extraction unit 17.

Reference value storage unit 14 stores a first reference value that is a value of voltage Vce measured before start of use of semiconductor device 2 (that is, an unused state). The first reference value is measured when semiconductor module 30 is in the ON state.

Reference value storage unit 15 stores a second reference value that is a value of voltage Vee measured before the start of the use of semiconductor device 2 (that is, the unused state). The second reference value is measured when semiconductor module 30 is in the ON state.

The first reference value and the second reference value are preferably representative values of values repeatedly measured under an environment suitable for measuring voltages Vce, Vee.

Temporal change extraction unit 16 compares voltage Vce output from Vce amplifier 12 with the first reference value stored in reference value storage unit 14 to extract a temporal change of voltage Vce according to elapsed time from a time point when the first reference value is measured. Specifically, temporal change extraction unit 16 calculates a value indicating the temporal change of voltage Vce (hereinafter, referred to as “temporal change amount ΔVce”). Temporal change amount ΔVce is, for example, a difference between a value of voltage Vce output from Vce amplifier 12 and the first reference value, a magnification of the value of voltage Vce output from Vce amplifier 12 with respect to the first reference value, a value obtained by subtracting a first constant from the magnification, or the like. The first constant is, for example, 1.

Temporal change extraction unit 17 compares voltage Vee output from Vee amplifier 13 with the second reference value stored in reference value storage unit 15 to extract a temporal change of voltage Vee according to elapsed time from a time point when the second reference value is measured. Specifically, temporal change extraction unit 17 calculates a value indicating the temporal change of voltage Vee (hereinafter, referred to as “temporal change amount ΔVee”). Temporal change amount ΔVee is, for example, a difference between a value of voltage Vee output from Vee amplifier 13 and the second reference value, a magnification of the value of voltage Vee output from Vee amplifier 13 with respect to the second reference value, a value obtained by subtracting a second constant from the magnification, or the like. The second constant is, for example, 1.

Correlation value calculation unit 18 calculates a correlation value between the temporal change of voltage Vce and the temporal change of voltage Vee. Specifically, correlation value calculation unit 18 calculates a correlation value between temporal change amount ΔVce calculated by temporal change extraction unit 16 and temporal change amount ΔVee calculated by temporal change extraction unit 17. The correlation value is, for example, a difference between temporal change amount ΔVce and temporal change amount ΔVee, a ratio obtained by dividing temporal change amount ΔVee by temporal change amount ΔVce, or the like. Correlation value calculation unit 18 stores the calculated correlation value in storage unit 19.

Storage unit 19 stores the correlation value calculated by correlation value calculation unit 18 in association with time information.

Temporal change calculation unit 20 calculates a temporal change amount ΔCor indicating a temporal change of the correlation value by using the correlation value calculated by correlation value calculation unit 18 and a past correlation value stored in storage unit 19. Temporal change amount ΔCor is, for example, an absolute value of the correlation value calculated by correlation value calculation unit 18 or a difference between the correlation value calculated by correlation value calculation unit 18 and the past correlation value stored in storage unit 19. The past correlation value is, for example, a latest correlation value among the correlation values stored in storage unit 19, a correlation value at a time earlier by a predetermined period from a current time point among the correlation values stored in storage unit 19, or the like. Alternatively, temporal change amount ΔCor may be a value obtained by dividing the difference between the correlation value calculated by correlation value calculation unit 18 and the past correlation value stored in storage unit 19 by an elapsed time (that is, a first-order differential coefficient by time). The elapsed time is a time from a time indicated by the time information corresponding to the past correlation value to the current time point. Temporal change amount ΔCor may be a value obtained by further dividing the value by the elapsed time, the value being obtained by dividing the difference between the correlation value calculated by correlation value calculation unit 18 and the past correlation value stored in storage unit 19 by the elapsed time (that is, a second-order differential coefficient by time).

Service life diagnostic unit 21 diagnoses the service life of semiconductor device 2 on the basis of temporal change amount ΔCor calculated by temporal change calculation unit 20. Specifically, service life diagnostic unit 21 diagnoses the service lives of collector-side main circuit connecting portion 10 and emitter-side main circuit connecting portion 11 on the basis of temporal change amount ΔCor. Service life diagnostic unit 21 displays information indicating the diagnosis result (hereinafter, it is referred to as “service life information”) on display unit 4. As a result, a user of semiconductor device 2 can perform maintenance of semiconductor device 2 at appropriate timing by checking the service life information.

### (Internal Structure of Semiconductor Module)

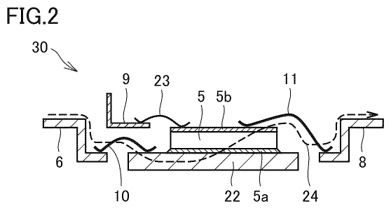

FIG. 2 is a schematic cross-sectional view illustrating one example of an internal structure of the semiconductor module. As illustrated in FIG. 2, semiconductor module 30 includes semiconductor element 5. Semiconductor element 5 is generally obtained by performing electrode processing on a flat plate-shaped semiconductor. In the example illustrated in FIG. 2, semiconductor element 5 includes a collector electrode 5a formed on a lower surface of a semiconductor and an emitter electrode 5b formed on an upper surface of the semiconductor.

Collector electrode 5a is connected to a metal plate 22. Metal plate 22 is connected to collector main terminal 6 via collector-side main circuit connecting portion 10. In the example of FIG. 2, a bonding wire is used as collector-side main circuit connecting portion 10. Aluminum, copper, or another alloy is used as a material of the bonding wire. The bonding wire is bonded to a terminal or an electrode by being crushed by applying ultrasonic waves.

Emitter electrode 5b is connected to emitter main terminal 8 via emitter-side main circuit connecting portion 11. In the example of FIG. 2, a bonding wire is used as the emitter-side main circuit connecting portion 11. Further, emitter electrode 5b is connected to emitter reference terminal 9 via a connection portion 23. A bonding wire is used as connection portion 23.

In FIG. 2, a large current flows in a path 24 of the current flowing from collector main terminal 6 to emitter main terminal 8. On the other hand, a large current does not flow through connection portion 23 connecting emitter reference terminal 9 and emitter electrode 5b.

By alternately switching between the ON state and the OFF state in semiconductor module 30, a state in which a large current flows through path 24 and a state in which no current flows through path 24 are repeated. As a result, a calorific value of semiconductor element 5 greatly fluctuates, and a temperature of semiconductor element 5 rises or falls. As a result, due to a difference in thermal expansion coefficient between the metal connected to semiconductor element 5 and semiconductor element 5, strain is repeatedly applied between semiconductor element 5 and the metal, and a joint portion between semiconductor element 5 and the metal is likely to deteriorate.

In the example illustrated in FIG. 2, collector electrode 5a is connected to collector-side main circuit connecting portion 10 via metal plate 22. A contact area between collector electrode 5a and metal plate 22 is much larger than a contact area between emitter electrode 5b and emitter-side main circuit connecting portion 11.

Therefore, a joint portion between semiconductor element 5 and metal plate 22 is hardly affected by distortion due to heat. Note that collector-side main circuit connecting portion 10 and metal plate 22 are both made of metal. Therefore, although a contact area between collector-side main circuit connecting portion 10 and metal plate 22 is small, a joint portion between collector-side main circuit connecting portion 10 and metal plate 22 is hardly affected by the distortion due to heat.

On the other hand, emitter-side main circuit connecting portion 11 is directly connected to emitter electrode 5b, and the contact area between emitter-side main circuit connecting portion 11 and emitter electrode 5b is small. Therefore, a joint portion between semiconductor element 5 and emitter-side main circuit connecting portion 11 is easily affected by distortion due to heat. Similarly, connection portion 23 is directly connected to emitter electrode 5b, and a contact area between connection portion 23 and emitter electrode 5b is small. Therefore, a joint portion between semiconductor element 5 and connection portion 23 is also easily affected by distortion due to heat. However, a current flowing through emitter-side main circuit connecting portion 11 is larger than a current flowing through the connection portion 23. Therefore, a joint portion between semiconductor element 5 and emitter-side main circuit connecting portion 11 directly receives heat generated by semiconductor element 5, and thus deteriorates earliest.

### (Temporal Change of Voltages Vce, Vee)

Next, an example of the temporal changes in voltages Vce, Vee due to deterioration of the joint portions will be described. Voltage Vce is a voltage between collector main terminal 6 and emitter main terminal 8 in path 24 illustrated in FIG. 2. Voltage Vee is a voltage between emitter reference terminal 9 and emitter main terminal 8. Emitter reference terminal 9 is not present on path 24. As described above, voltages Vce, Vee are voltages on different paths from each other. Therefore, the temporal changes of voltages Vce and Vee due to deterioration of the joint portions may be different from each other.

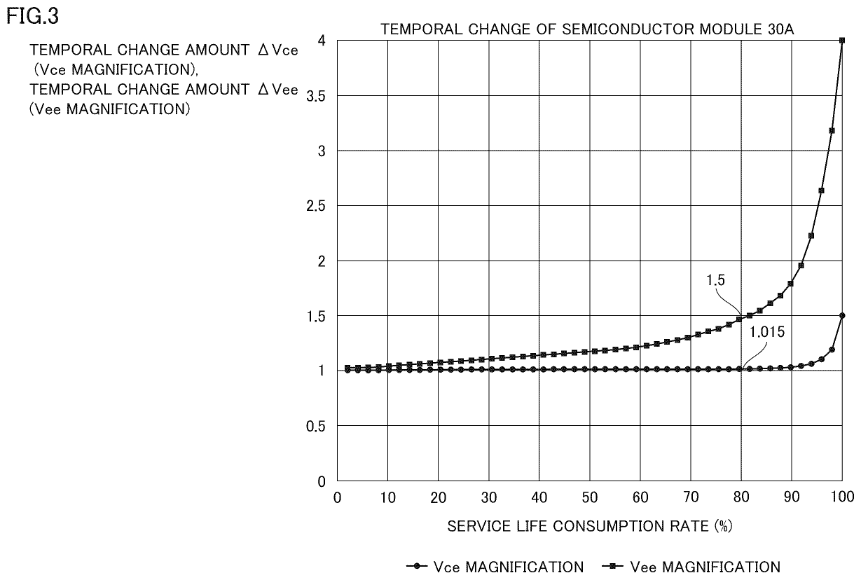

FIG. 3 is a diagram illustrating a relationship between a degree of progress deterioration (service life consumption rate) of a semiconductor module 30A and the temporal changes of voltages Vce, Vee. FIG. 3 illustrates “magnifications with respect to the reference values” as temporal change amounts ΔVce, ΔVee. That is, the magnification of a value of voltage Vce output from Vce amplifier 12 with respect to the first reference value (hereinafter, referred to as “Vce magnification”) and the magnification of a value of voltage Vee output from Vee amplifier 13 with respect to the second reference value (hereinafter referred to as “Vee magnification”) are graphed. In FIG. 3, a vertical axis represents the magnification with respect to the reference value (Vce magnification, Vee magnification). A horizontal axis represents a ratio obtained by dividing the elapsed time from the start of use by an entire service life period in which the semiconductor module becomes unusable (hereinafter, referred to as “service life consumption rate”).

As illustrated in FIG. 3, the Vce magnification and the Vee magnification increase over time (that is, increase in service life consumption rate). At the start of use of semiconductor module 30A (that is, at a time point of the service life consumption rate of 0%), voltages Vce, Vee are the same as the first and second reference values, respectively. Therefore, both the Vce magnification and the Vee magnification are 1.

As the deterioration of each the joint portions progresses with the lapse of time, an electrical resistance of the joint portion increases. Therefore, voltages Vce, Vee increase, and the Vce magnification and the Vee magnification also increase. However, since voltages Vce, Vee are voltages on different paths, behaviors of the Vce magnification and the Vee magnification with respect to the progress of deterioration of the joint portions are not the same. In the example illustrated in FIG. 3, the Vee magnification is always larger than the Vce magnification. For example, at a time point when the service life consumption rate is 80% (that is, a time point when 80% of the entire service life period has elapsed), the Vee magnification is 1.5, whereas the Vce magnification is 1.015. That is, the value of voltage Vee increases by 50% with respect to the second reference value, whereas the value of voltage Vce increases by only 1.5% with respect to the first reference value. At a time point of the service life consumption rate of 100%, the Vee magnification is 4, whereas the Vce magnification is 1.5.

In service life prediction of the semiconductor module, it is important to accurately predict how much more the semiconductor module can be used in the middle of being used, that is, the remaining service life. For example, if it is possible to notify the user of the semiconductor module of “remaining service life 20%” as service life diagnosis information when the service life of the semiconductor module reaches remaining 20%, the user of the semiconductor module can perform planned maintenance such as arranging replacement of the semiconductor module in advance. If accuracy of the prediction is low, the semiconductor module comes to the end of its service life and becomes unusable before the user performs the replacement operation, which may cause a problem that the semiconductor device cannot be used.

Conventionally, remaining service life information is notified on the basis of changes in the Vce magnification and the Vee magnification as illustrated in FIG. 3. For example, at timing when the Vee magnification reaches 1.5, the remaining service life information indicating that the remaining service life is 20% is notified.

However, in such a method of the related art, service life prediction accuracy is lower. This is because there is an individual difference in the characteristics of semiconductor modules 30, and even in semiconductor modules 30 having the same specifications, the changes in temporal change amounts ΔVce, ΔVee with respect to the service life consumption rate can be different due to the individual difference in semiconductor modules 30.

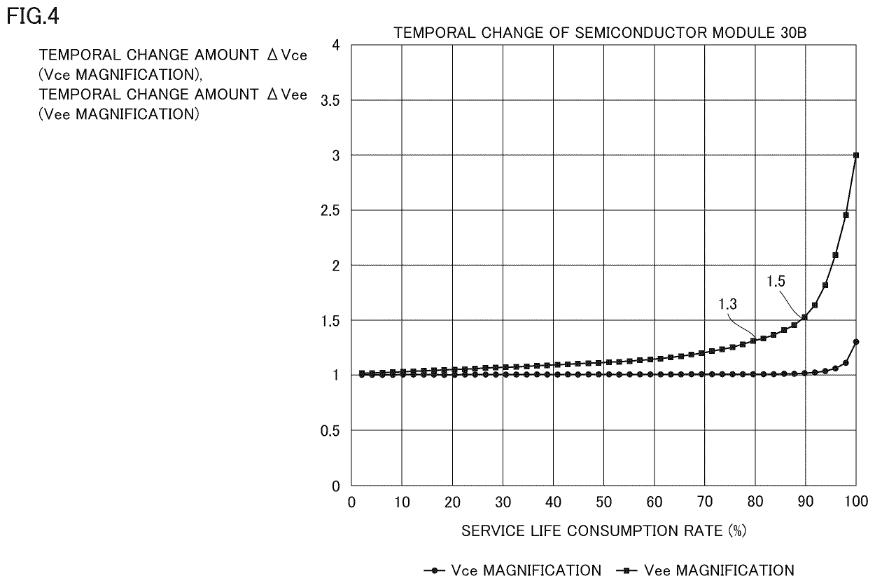

FIG. 4 is a diagram illustrating relationships between a degree of progress of deterioration (service life consumption rate) of a semiconductor module 30B and temporal changes of voltages Vce, Vee. Semiconductor module 30B is a separate module having the specification as the specification of semiconductor module 30A. Similarly to FIG. 3, FIG. 4 illustrates a graph in which a vertical axis represents the magnification (Vce magnification, Vee magnification) with respect to reference values and a horizontal axis represents the service life consumption rate.

As illustrated in FIG. 4, in semiconductor module 30B, the Vce magnification and the Vee magnification also increase over time (that is, increase in service life consumption rate). However, changes in the Vce magnification and the Vee magnification in semiconductor module 30B are different from the changes in the Vce magnification and the Vee magnification in semiconductor module 30A. Specifically, the time point when the Vee magnification becomes 1.5 is a time point when the service life consumption rate becomes 80% in semiconductor module 30A, whereas it is a time point when the service life consumption rate becomes 90% in semiconductor module 30B. In semiconductor module 30B, the Vee magnification is 1.3 at a time point of the service life consumption rate of 80%.

When the service life diagnosis method of notifying the remaining service life information indicating that the remaining service life is 20% at the timing when the Vee magnification reaches 1.5 on the basis of the changes in the Vce magnification and the Vee magnification as illustrated in FIG. 3 is adopted, a problem below occurs. That is, when the service life diagnosis method is applied to semiconductor module 30B, the remaining service life information indicating that the remaining service life is 20% is notified at the time of the service life consumption rate of 90%. As described above, the remaining service life information indicating the remaining service life different from the actual remaining service life is notified, and the accuracy of the service life diagnosis is low.

In view of such a problem, service life diagnostic device 1 according to the first embodiment performs service life diagnosis with higher accuracy by using the correlation value between the temporal change of voltage Vce and the temporal change of voltage Vee. A reason why the accuracy of the service life diagnosis is improved by using the correlation value will be described below.

### (Improvement in Accuracy of Service Life Diagnosis)

Parameters indicating the characteristic of semiconductor module 30 include various parameters in addition to voltages Vce, Vee. In general, values of these parameters vary in individuals even in semiconductor modules 30 having the same specification. This is considered to be caused by variations in quality of members, variations in processing conditions in a manufacturing process, and the like. As described above, variations in the values of the parameters indicating the characteristics occur in individuals, but in the same individual, a correlation between the values of these parameters is maintained. This is because a factor that determines magnitudes of the values of these parameters depend on a product specification, that is, a design. For example, if temporal change amount ΔVce increases under a certain manufacturing condition, temporal change amount ΔVee similarly increases. Therefore, the correlation between temporal change amounts ΔVce, ΔVee is the same as long as the products have the same specification even if the individuals are different. That is, the correlation between temporal change amounts ΔVce, ΔVee in the plurality of semiconductor modules 30 having the same specification is constant.

For example, as illustrated in FIG. 3, in semiconductor module 30A, temporal change amount ΔVee of temporal change amounts ΔVce, ΔVee with respect to the service life consumption rate increases earlier, and an increase rate gradually increases toward an end stage of the service life. On the other hand, temporal change amount ΔVce does not easily increase from an initial stage to a middle stage, and maintains a value considerably lower than temporal change amount ΔVee. The increase rate of temporal change amount ΔVce rapidly increases toward an end stage. Such a relationship can also be seen in temporal change amounts ΔVce, ΔVee in semiconductor module 30B illustrated in FIG. 4. The values of temporal change amounts ΔVce, ΔVee in semiconductor module 30B are smaller than temporal change amounts ΔVce, ΔVee in semiconductor module 30A. Therefore, the values of temporal change amounts ΔVce, ΔVee in semiconductor module 30B cannot be simply compared with the values of temporal change amounts ΔVce, ΔVee in semiconductor module 30A. However, the correlation between temporal change amounts ΔVce, ΔVee in semiconductor module 30B is the same as the correlation between temporal change amounts ΔVce, ΔVee in semiconductor module 30A. That is, a shape of the graph illustrated in FIG. 4 has a shape obtained by reducing a shape of the graph illustrated in FIG. 3 along the vertical axis.

In the present disclosure, the service life of semiconductor module 30 is diagnosed using the fact that the correlation of the characteristics in the plurality of semiconductor modules 30 having the same specification is constant. Specifically, in the first embodiment, the correlation between temporal change amounts ΔVce, ΔVee is used. As a result, it is possible to perform highly accurate service life diagnosis excluding individual variations.

### (First Service Life Diagnosis Example)

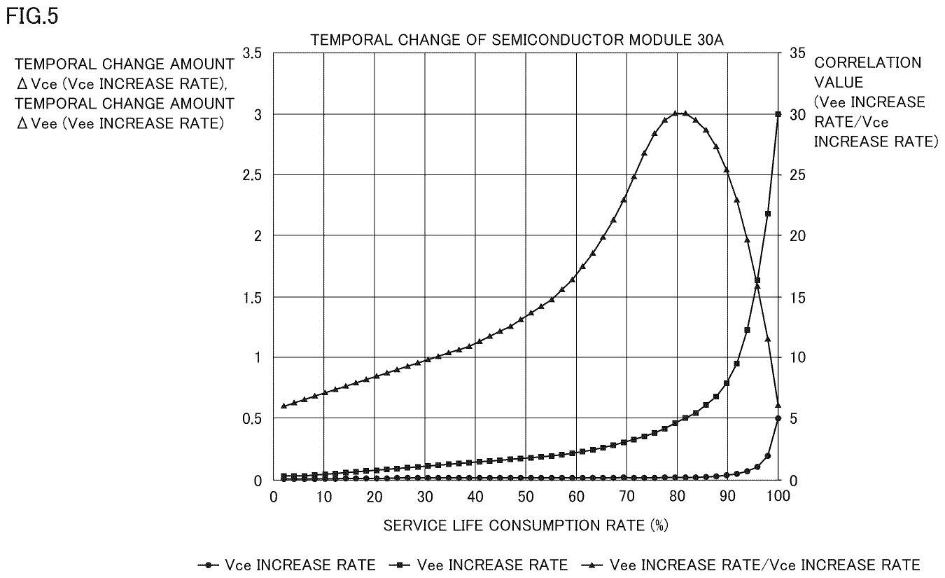

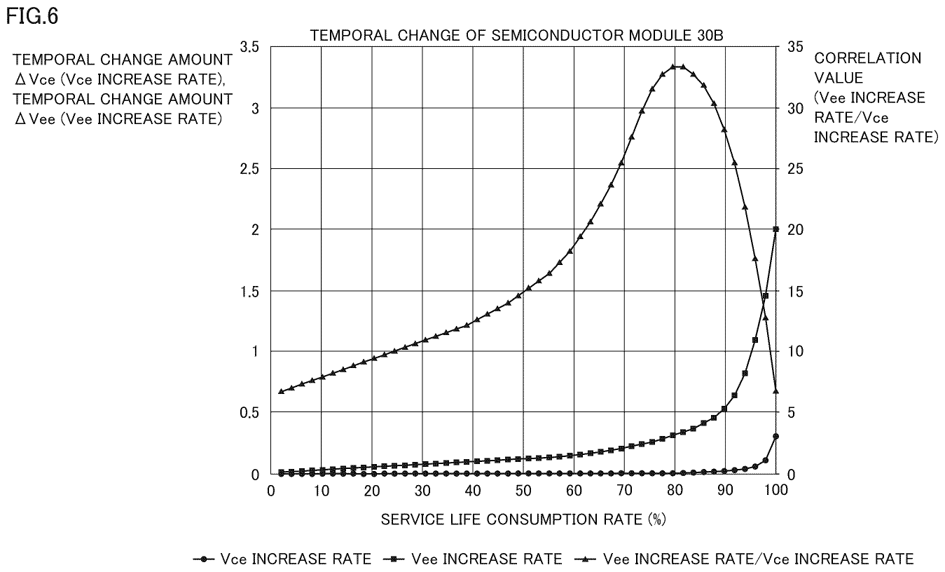

A first service life diagnosis example by diagnostic processing unit 3 will be described with reference to FIGS. 5, 6. FIG. 5 is a diagram illustrating the correlation between temporal change amounts ΔVce, ΔVee in semiconductor modules 30A. FIG. 6 is a diagram illustrating the correlation between temporal change amounts ΔVce, ΔVee in semiconductor modules 30B. FIGS. 5, 6 illustrate an example in which a value obtained by subtracting a first constant “1” from the magnification of voltage Vce with respect to the first reference value (hereinafter, referred to as “Vce increase rate”) is extracted as temporal change amount ΔVce. Similarly, FIGS. 5, 6 illustrate an example in which a value obtained by subtracting a second constant “1” from the magnification of voltage Vee with respect to the second reference value (hereinafter, referred to as “Vee increase rate”) is extracted as temporal change amount ΔVee. FIGS. 5. 6 illustrate graphs in which a horizontal axis represents the service life consumption rate, a left vertical axis represents the Vce increase rate and the Vee increase rate, and a right vertical axis represents the correlation value. The correlation value is a value of a ratio obtained by dividing the Vee increase rate by the Vce increase rate.

Unlike the Vce increase rate and the Vee increase rate, the correlation value indicating the correlation between temporal change amounts ΔVce, ΔVee does not monotonically increase, but becomes a curve having a mountain-like peak in which the correlation value once increases and then changes to fall. A reason for this is that, as described above, there is a difference in the characteristics that voltage Vee increases early and continues to rise relatively monotonically, whereas voltage Vce does not easily increase in the initial stage, and rapidly increases in the end stage. Due to this difference, the correlation value increases by strongly reflecting the increase in voltage Vee in the initial stage, but voltage Vce starts to increase suddenly toward the end stage, so that the increase in the correlation value is suppressed and the correlation value becomes maximum. Thereafter, in the end stage, the increase rate of voltage Vce rapidly increases, and thus the correlation value turns to decrease. Therefore, the correlation value becomes a mountain-like curve having a peak.

As illustrated in FIGS. 5, 6, the graph shape indicating the temporal change of the correlation value in semiconductor module 30A coincides with the graph shape indicating the temporal change of the correlation value in semiconductor module 30B. Specifically, as illustrated in FIG. 5, in the case of semiconductor module 30A, a time point when the correlation value becomes maximum, that is, a time point when the first-order differential coefficient of the correlation value becomes 0 is a time point when the service life consumption rate is 80%. As illustrated in FIG. 6, in the case of semiconductor module 30B, a time point when the correlation value becomes maximum, that is, a time point when the first-order differential coefficient of the correlation value becomes 0 is also a time point when the service life consumption rate is 80%. As described above, the time point when the correlation value becomes maximum is the time point when the service life consumption rate is 80% in both semiconductor modules 30A and 30B.

Therefore, temporal change calculation unit 20 calculates the first-order differential coefficient of the correlation value as temporal change amount ΔCor indicating the temporal change of the correlation value. Service life diagnostic unit 21 can determine that the remaining service life is 20% in accordance with a fact that the first-order differential coefficient of the correlation value becomes 0. As a result, it is possible to perform highly accurate service life diagnosis excluding individual variations.

Alternatively, temporal change calculation unit 20 may further calculate the second-order differential coefficient of the correlation value as temporal change amount ΔCor indicating the temporal change of the correlation value. Service life diagnostic unit 21 may perform the service life diagnosis using not only the first-order differential coefficient of the correlation value but also the second-order differential coefficient.

For example, a time point when the second-order differential coefficient of the correlation value becomes 0 corresponds to an inflection point of the curve of the correlation value, and is a time point when the increasing rate of the correlation value turns from an increase to a decrease. As illustrated in FIGS. 5, 6, in the case of both semiconductor modules 30A, 30B, a time point when the second-order differential coefficient of the correlation value becomes 0 is a time point when the service life consumption rate is 70%. Therefore, service life diagnostic unit 21 can determine that the remaining service life is 30% in accordance with a fact that the second-order differential coefficient of the correlation value becomes 0. As a result, it is possible to perform highly accurate service life diagnosis excluding individual variations.

Furthermore, temporal change calculation unit 20 may calculate a ratio between a peak value, which is the correlation value when the first-order differential coefficient becomes 0, and the correlation value thereafter as temporal change amount ΔCor indicating the temporal change of the correlation value. By checking the ratio, service life diagnostic unit 21 may diagnose that the service life consumption rate is 96% and the remaining service life is 4% in accordance with a fact that the correlation value decreases to half of the peak value. As a result, service life diagnostic unit 21 can display a terminal alarm on display unit 4.

### (Second Service Life Diagnosis Example)

In the first service life diagnosis example, since the Vce increase rate (the value obtained by subtracting the first constant “1” from the magnification of voltage Vce with respect to the first reference value) is extracted as temporal change amount ΔVce, temporal change amount ΔVce is close to 0 in the initial stage. Similarly, since the Vee increase rate (the value obtained by subtracting the second constant “1” from the magnification of the voltage Vee with respect to the second reference value) is extracted as temporal change amount ΔVee, temporal change amount ΔVee is close to 0 in the initial stage. Therefore, when the ratio obtained by dividing temporal change amount ΔVee by temporal change amount ΔVce is calculated as the correlation value, the correlation value may greatly vary. This is because the correlation value is calculated by dividing a small value close to 0 by a small value close to 0. As a result, slight fluctuation in the measured values of voltages Vce, Vee may cause a large variation in the correlation value. Therefore, the correlation value tends to be inaccurate in the initial stage.

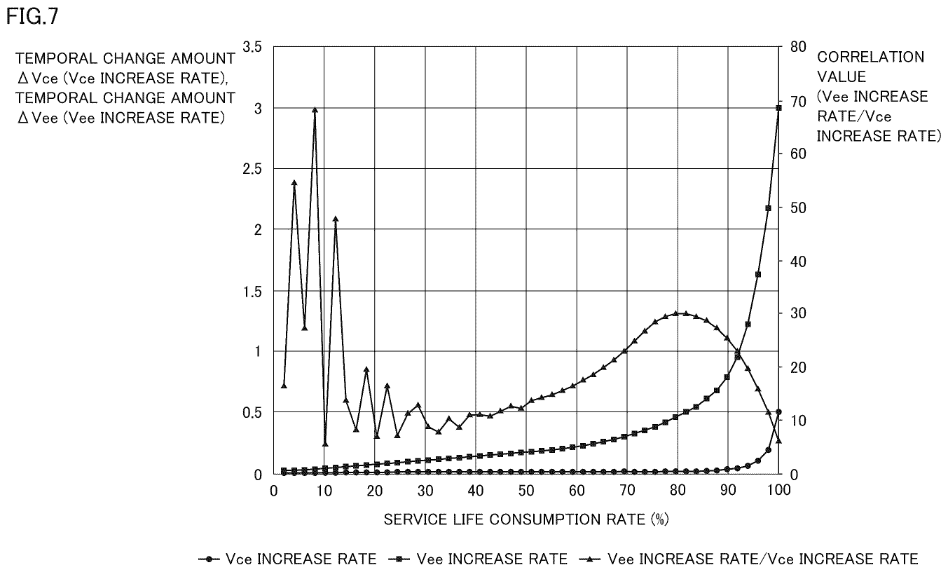

FIG. 7 is a diagram illustrating an influence of slight fluctuations in the values of voltages Vce and Vee. When the values of voltages Vce, Vee fluctuate due to a problem of measurement accuracy of the voltages, as illustrated in FIG. 7, in the initial stage, the correlation value, which is the ratio obtained by dividing temporal change amount ΔVee (Vee increase rate) by temporal change amount ΔVce (Vce increase rate), greatly fluctuates. Such large variations in the correlation values can affect the service life diagnosis.

Therefore, temporal change extraction unit 16 extracts a value obtained by subtracting the first constant “0” from the Vce magnification (that is, the Vce magnification itself) as temporal change amount ΔVce. Therefore, temporal change extraction unit 17 extracts a value obtained by subtracting the second constant “0” from the Vee magnification (that is, the Vee magnification itself) as temporal change amount ΔVee. Then, correlation value calculation unit 18 may calculate a ratio obtained by dividing the Vee magnification by the Vce magnification (Vee magnification/Vce magnification) as the correlation value indicating the correlation between the temporal change of voltage Vce and the temporal change of voltage Vee.

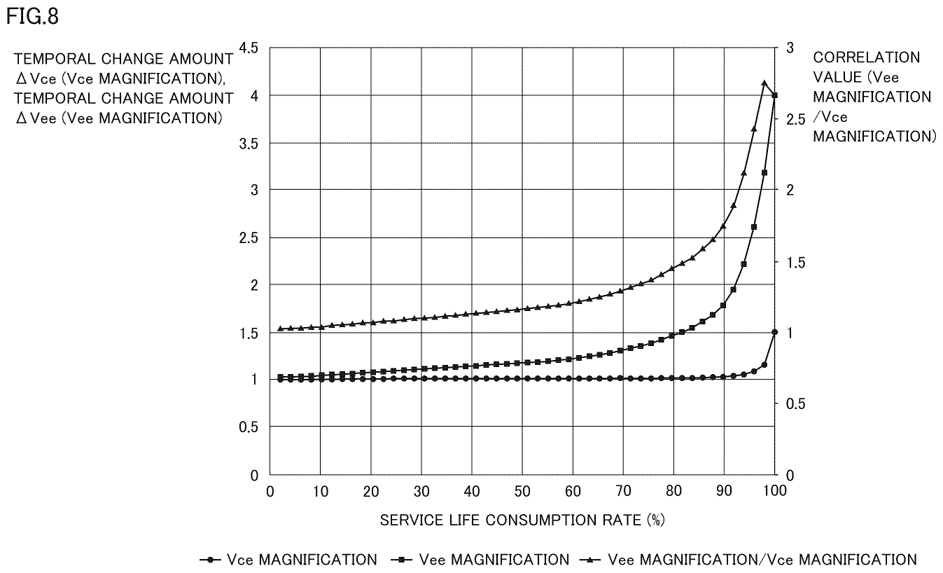

FIG. 8 is a diagram illustrating a temporal change of the correlation value “Vee magnification/Vce magnification” calculated in the second service life diagnosis example. As illustrated in FIG. 8, since the Vce magnification and the Vee magnification are extracted as temporal change amounts ΔVce, ΔVee, respectively, temporal change amounts ΔVce, ΔVee are stable without being affected by slight fluctuations in the measured values of voltages Vce and Vee. That is, the correlation value “Vee magnification/Vce magnification” gradually increases as the service life consumption rate increases in the initial stage. This makes it possible to monitor minute deterioration of the joint portions in the initial stage.

However, the correlation value “Vee magnification/Vce magnification” is not suitable for detecting a sudden increase in voltage Vce near the end stage. Therefore, temporal change extraction units 16, 17 extract the Vce magnification and the Vee magnification, respectively, as temporal change amounts ΔVce, ΔVee until timing at which the stable Vce increase rate and Vee increase rate can be extracted (hereinafter, referred to as “switching timing”). After the switching timing, temporal change extraction units 16, 17 extract the Vce increase rate and the Vee increase rate as temporal change amounts ΔVce, ΔVee, respectively. Correlation value calculation unit 18 calculates the correlation value “Vee magnification/Vce magnification” until the switching timing as the correlation value indicating the correlation between the temporal change of voltage Vce and the temporal change of voltage Vee, and calculates the correlation value “Vee increase rate/Vce increase rate” after the switching timing. As a result, service life diagnostic unit 21 can diagnose the service life using the temporal change in the correlation value “Vee magnification/Vce magnification” in the initial stage, and can diagnose the service life using the temporal change in the correlation value “Vee increase rate/Vce increase rate” in the end stage. As a result, both initial deterioration and final deterioration can be accurately monitored.

Note that the constant subtracted from the magnification is not limited to 0 or 1, and may change from a value close to 0 to a value close to 1 from the initial stage to the final stage. As a result, it is possible to calculate a more appropriate correlation value for service life prediction according to use of semiconductor module 30.

### Advantages

As described above, service life diagnostic device 1 according to the first embodiment includes Vce amplifier 12, Vee amplifier 13, and service life diagnostic unit 21. Vce amplifier 12 operates as a voltage measuring instrument to measure voltage Vce between collector main terminal 6 connected to the collector electrode of semiconductor element 5 mounted on semiconductor device 2, and emitter main terminal 8 connected to the emitter electrode of semiconductor element 5. Vee amplifier 13 operates as a voltage measuring instrument to measure voltage Vee between emitter main terminal 8 and emitter reference terminal 9 connected to the emitter electrode. Service life diagnostic unit 21 diagnoses the service life of semiconductor device 2 using the correlation value between the temporal change of voltage Vce and the temporal change of voltage Vee.

According to the above configuration, the correlation value between the temporal changes of voltages Vce, Vee is used for the service life diagnosis. Although the temporal changes of voltages Vce, Vee varies in individuals of semiconductor modules 30, the variation in the temporal change of the correlation value is small in individuals of semiconductor modules 30. Therefore, it is possible to perform the service life diagnosis with high accuracy in which influence by the individual difference of semiconductor modules 30 is eliminated.

Temporal change amount ΔVce of voltage Vce is indicated by, for example, the value obtained by subtracting the first constant from the magnification of the value of voltage Vce with respect to the first reference value (Vce magnification or Vce increase rate). Temporal change amount ΔVee of voltage Vee is indicated by, for example, the value obtained by subtracting the second constant from the magnification of the value of voltage Vee with respect to the second reference value (Vee magnification or Vee increase rate). The correlation value is, for example, the ratio between temporal change amount ΔVce and temporal change amount ΔVee (Vee magnification/Vce magnification or Vee increase rate/Vce increase rate).

By using the Vee magnification/Vce magnification or the Vee increase rate/Vce increase rate as the correlation value, the curve indicating the temporal change of the correlation value becomes a mountain shape having a peak at a specific service life consumption rate. Therefore, service life diagnostic unit 21 can detect that the specific service life consumption rate has been reached in accordance with a fact that the correlation value becomes maximum, and can output the service life information indicating the remaining service life. As a result, a user of semiconductor device 2 can perform maintenance of semiconductor device 2 at appropriate timing by checking the service life information.

The first constant and the second constant are, for example, 1. As a result, a difference between temporal change amount ΔVce and temporal change amount ΔVee increases in the end stage, and the accuracy of the service life diagnosis in the end stage can be increased.

The first constant and the second constant are, for example, 0. Accordingly, in the initial stage of use of semiconductor device 2, the correlation value becomes a stable value, and gradually increases as the service life consumption rate increases. This makes it possible to monitor minute deterioration of the joint portions inside semiconductor device 2 in the initial stage.

The first reference value is the value of voltage Vce measured before the start of use of semiconductor device 2. The second reference value is the value of voltage Vee measured before the start of use of semiconductor device 2.

Before use of the semiconductor device 2, it is possible to measure repeated values in an environment suitable for measurement of voltages Vce, Vee, and the values of voltages Vce, Vee can be measured with high accuracy. As a result, reliability of the correlation value calculated for the subsequent service life diagnosis is enhanced, and the accuracy of the service life diagnosis is improved.

### Second Embodiment

In the first embodiment, values of voltages Vce, Vee measured before the start of use of semiconductor device 2 (that is, in an unused state) are used as the first and second reference values, respectively. However, in this case, the service life diagnosis of semiconductor device 2 in which voltages Vce, Vee have not been measured before the start of use cannot be performed.

Therefore, in order to diagnose the service life of semiconductor device 2 in which voltages Vce, Vee have not been measured before the start of use, reference value storage units 14, 15 according to a second embodiment store the values of voltages Vce and Vee measured after the start of use of the semiconductor device 2 as the first and second reference values, respectively.

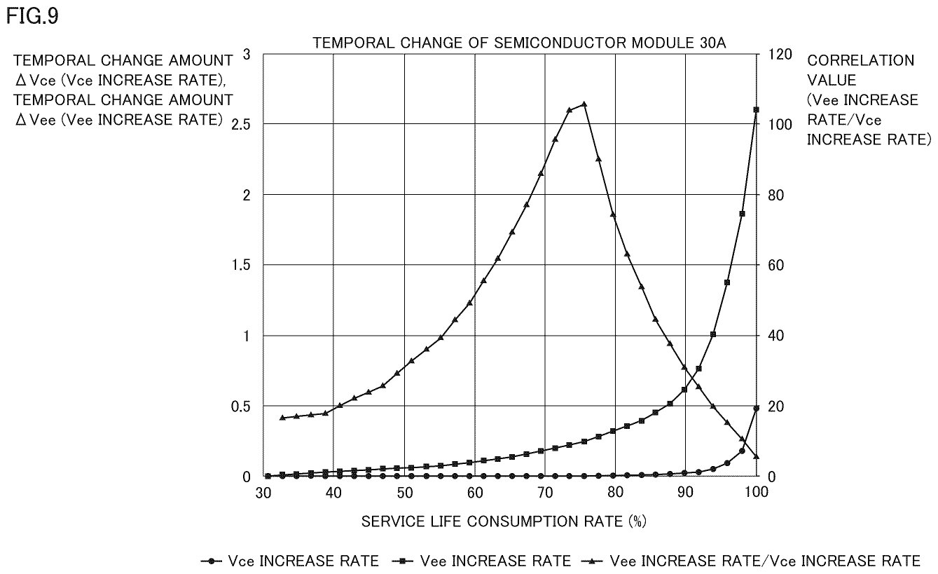

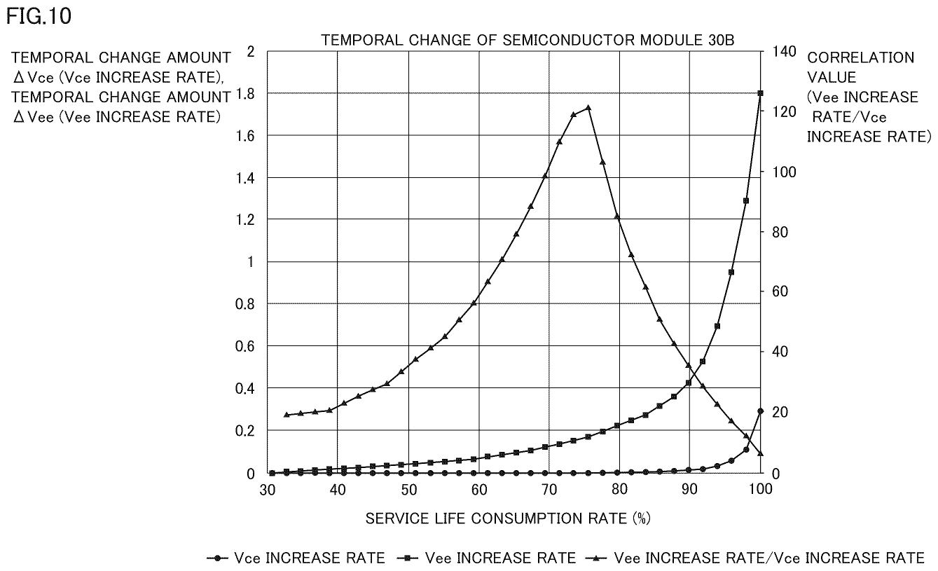

FIG. 9 is a diagram illustrating the correlation between temporal change amounts ΔVce, ΔVee in semiconductor modules 30A when the voltages at a time point of the service life consumption rate of 30% are used as the reference values. FIG. 10 is a diagram illustrating the correlation between temporal change amounts ΔVce, ΔVee in semiconductor modules 30B when the voltages at the time point of the service life consumption rate of 30% are used as the reference values. Similarly to FIGS. 5, 6, FIGS. 9, 10 each illustrate a graph in which a horizontal axis represents the service life consumption rate, a left vertical axis represents temporal change amounts ΔVce, ΔVee (Vce increase rate, Vee increase rate), and a right vertical axis represents the correlation value “Vee magnification/Vce magnification”.

As illustrated in FIGS. 9 and 10, the values of temporal change amounts ΔVce, ΔVee at the same service life consumption rate are different between semiconductor module 30A and semiconductor module 30B. That is, the service life consumption rate cannot be estimated and the remaining service life cannot be predicted only from the values of temporal change amounts ΔVce, ΔVee.

On the other hand, the curve of the correlation value “Vee increase rate/Vce increase rate” shows the same shape in semiconductor module 30A and semiconductor module 30B. Specifically, the curve of the correlation value “Vee increase rate/Vce increase rate” is a mountain shape having a peak near the service life consumption rate of 76%. Therefore, service life diagnostic unit 21 can more accurately diagnose the service life of semiconductor module 30 on the basis of the curve of the correlation value regardless of the individual difference in semiconductor modules 30.

When the voltages at a time point other than the time point of the service life consumption rate of 30% are used as the reference values, the curve indicating the temporal change of the correlation value has a shape different from the curves illustrated in FIGS. 9, 10. However, the curve indicating the temporal change of the correlation value shows the same shape regardless of the individual difference in the semiconductor modules 30.

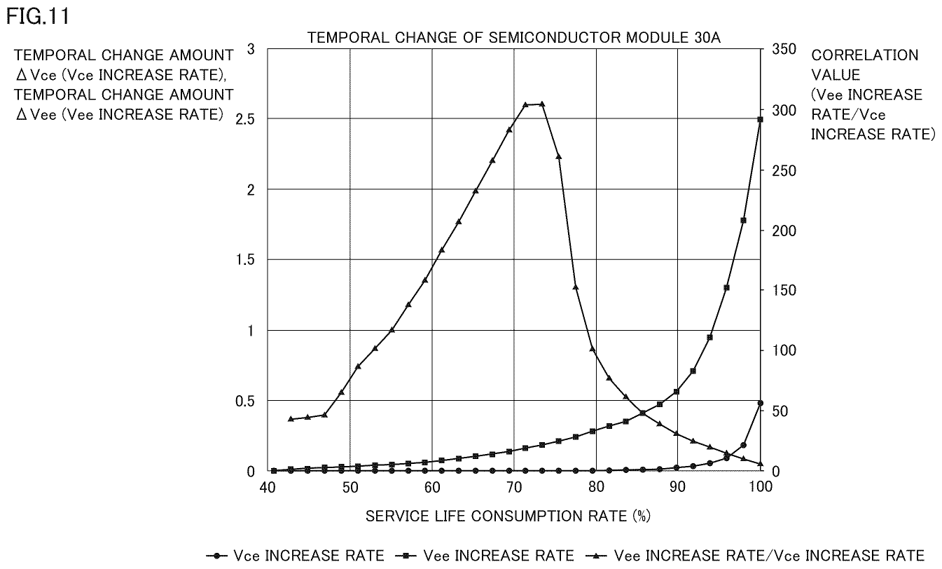

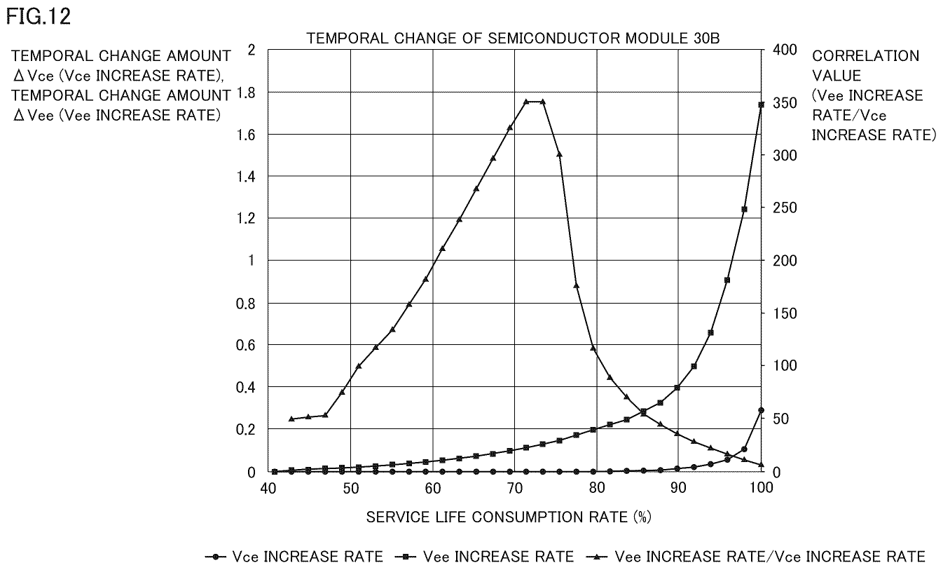

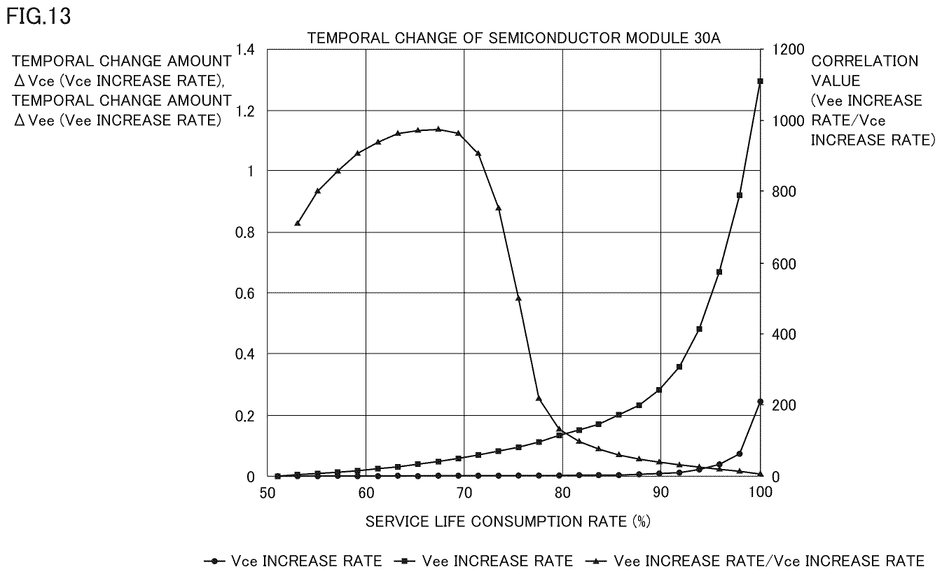

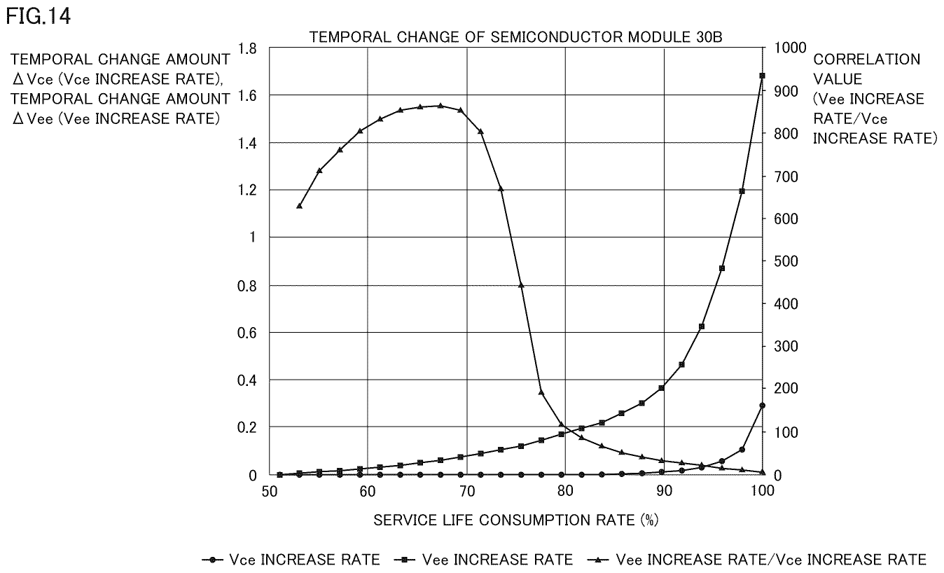

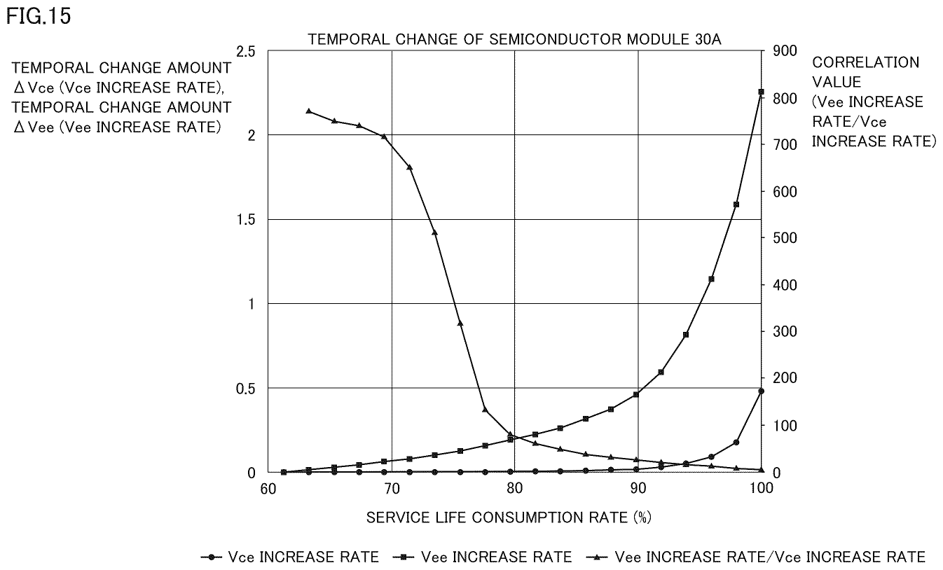

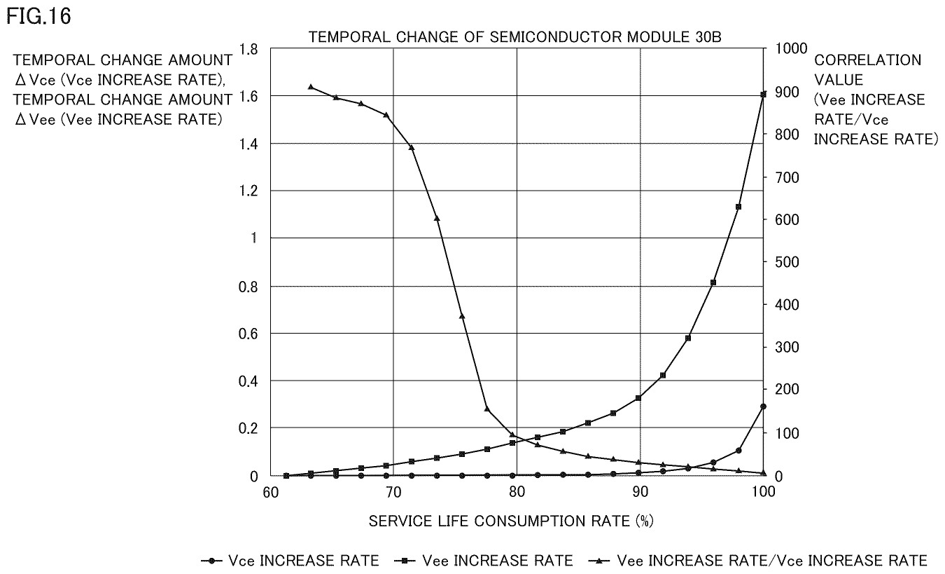

FIG. 11 is a diagram illustrating the correlation between temporal change amounts ΔVce, ΔVee in semiconductor modules 30A when the voltages at a time point of the service life consumption rate of 40% are used as the reference values. FIG. 12 is a diagram illustrating the correlation between temporal change amounts ΔVce, ΔVee in semiconductor modules 30B when the voltages at the time point of the service life consumption rate of 40% are used as the reference values. FIG. 13 is a diagram illustrating the correlation between temporal change amounts ΔVce, ΔVee in semiconductor modules 30A when the voltages at a time point of the service life consumption rate of 50% are used as the reference values. FIG. 14 is a diagram illustrating the correlation between temporal change amounts ΔVce, ΔVee in semiconductor modules 30B when the voltages at the time point of the service life consumption rate of 50% are used as the reference values. FIG. 15 is a diagram illustrating the correlation between temporal change amounts ΔVce, ΔVee in semiconductor modules 30A when the voltages at a time point of the service life consumption rate of 60% are used as the reference values. FIG. 16 is a diagram illustrating the correlation between temporal change amounts ΔVce, ΔVee in semiconductor modules 30B when the voltages at the time point of the service life consumption rate of 60% are used as the reference values. Similarly to FIGS. 9, 10, FIGS. 11 to 16 each illustrate a graph in which a horizontal axis represents the service life consumption rate, a left vertical axis represents temporal change amounts ΔVce, ΔVee (Vce increase rate, Vee increase rate), and a right vertical axis represents the correlation value “Vee magnification/Vce magnification”.

As illustrated in FIGS. 11 to 16, curves each indicating the temporal change of the correlation value “Vee increase rate/Vce increase rate” have the same shape when the service life consumption rates at the time of measuring the voltages set as the reference values are the same. That is, the curve of the correlation value illustrated in FIG. 11 has the same shape as the curve of the correlation value illustrated in FIG. 12. The curve of the correlation value illustrated in FIG. 13 has the same shape as the curve of the correlation value illustrated in FIG. 14. The curve of the correlation value illustrated in FIG. 15 has the same shape as the curve of the correlation value illustrated in FIG. 16.

When the values of voltages Vce, Vee measured after the start of use of semiconductor device 2 are used as the first and second reference values, respectively, the service life consumption rate at the time of measurement is usually unknown. However, as illustrated in FIGS. 9 to 16, the shape of the curve of the correlation value depends on the service life consumption rate at the time of measuring voltages Vce, Vee used as the first and second reference values. Therefore, service life diagnostic unit 21 stores in advance a plurality of curves of correlation values having different service life consumption rates at the time of measuring voltages Vce, Vee used as the first and second reference values. Service life diagnostic unit 21 compares the curve indicating the temporal change of the correlation value output from temporal change calculation unit 20 with the plurality of curves stored in advance. Service life diagnostic unit 21 may select, from the plurality of curves stored in advance, a curve having a highest degree of coincidence with the curve indicating the temporal change of the correlation value output from temporal change calculation unit 20, and diagnose the service life of semiconductor module 30 on the basis of the selected curve. For example, as illustrated in FIGS. 15, 16, when the correlation value consistently decreases from the start of measurement, service life diagnostic unit 21 can estimate that the service life consumption rate at the start of measurement exceeds 60%. In addition, when the selected curve is the curve illustrated in FIGS. 11, 12, service life diagnostic unit 21 can estimate that the service life consumption rate is about 73% in accordance with a change in the correlation value from the increase to the decrease.

As described above, in the second embodiment, even if the first and second reference values are set after the use of semiconductor device 2 is started, the service life diagnosis of semiconductor device 2 is possible.

### Third Embodiment

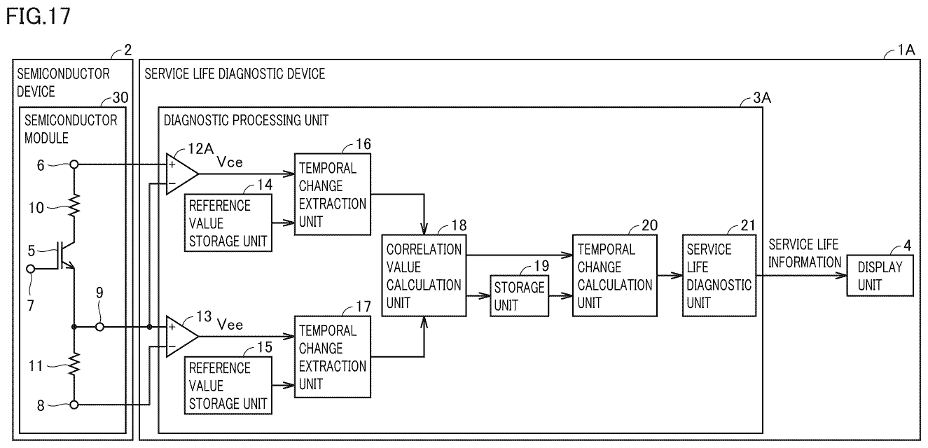

FIG. 17 is a block diagram illustrating one example of a configuration of a service life diagnostic device according to a third embodiment of the present disclosure. A service life diagnostic device 1A according to the third embodiment is different from service life diagnostic device 1 illustrated in FIG. 1 in that a diagnostic processing unit 3A is provided instead of diagnostic processing unit 3. Diagnostic processing unit 3A is different from diagnostic processing unit 3 in that a Vce amplifier 12A is included instead of Vce amplifier 12.

Vce amplifier 12A measures a voltage between collector main terminal 6 and emitter reference terminal 9, and amplifies the measurement result to voltage Vce suitable for post-processing. Vce amplifier 12A outputs voltage Vce to temporal change extraction unit 16.

Also in the third embodiment, similarly to the first embodiment, the service life of semiconductor device 2 can be diagnosed on the basis of the correlation value indicating the correlation between the temporal change of voltage Vce and the temporal change of voltage Vee. Note that in the third embodiment, voltage Vce is hardly affected by emitter-side main circuit connecting portion 11. Therefore, the difference between temporal change amount ΔVce and temporal change amount ΔVee may be enlarged as compared with the first embodiment. Therefore, the configuration of the first embodiment may be adopted or the configuration of the third embodiment may be adopted depending on the configuration of semiconductor module 30. Thus, the service life of semiconductor device 2 can be more appropriately diagnosed according to the configuration of semiconductor module 30.

### Fourth Embodiment

In a fourth embodiment, a semiconductor device to be diagnosed by the service life diagnostic device according to the first, second, and third embodiments is applied to a power conversion device. Although the present disclosure is not limited to a specific power conversion device, a case where the present disclosure is applied to a three-phase inverter will be described below as the fourth embodiment.

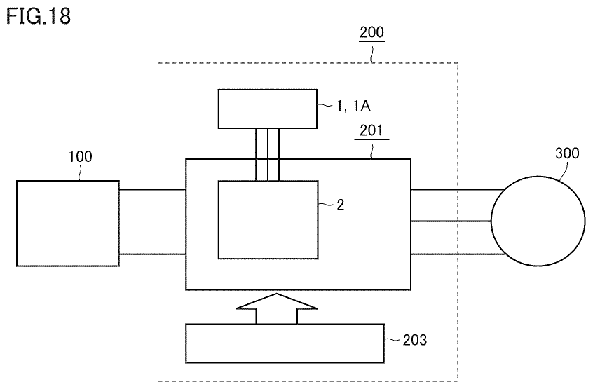

FIG. 18 is a block diagram illustrating a configuration of a power conversion system to which a power conversion device according to the fourth embodiment of the present disclosure is applied.

The power conversion system illustrated in FIG. 18 is configured of a power supply 100, a power conversion device 200, and a load 300. Power supply 100 is a DC power supply, and supplies a DC power to the power conversion device 200. Power supply 100 can be configured of various components, and can be configured of, for example, a DC system, a solar cell, and a storage battery, or may be configured of a rectifier circuit or an AC/DC converter connected to an AC system. In addition, power supply 100 may be configured by a DC/DC converter to convert a DC power output from the DC system into a predetermined power.

Power conversion device 200 is a three-phase inverter connected between power supply 100 and load 300, converts the DC power supplied from power supply 100 into an AC power, and supplies the AC power to load 300. As illustrated in FIG. 18, power conversion device 200 includes a main conversion circuit 201 to convert the DC power into the AC power and outputs the AC power, and a control circuit 203 to output a control signal for controlling main conversion circuit 201 to main conversion circuit 201. Further, power conversion device 200 includes service life diagnostic device 1 (or service life diagnostic device 1A) described above.

Load 300 is a three-phase electric motor driven by the AC power supplied from power conversion device 200. Note that load 300 is not limited to a specific application, but is an electric motor mounted on various types of electrical equipment, and is used as, for example, an electric motor for a hybrid vehicle, an electric vehicle, a railway vehicle, an elevator, or an air conditioner.

Hereinafter, details of power conversion device 200 will be described. Main conversion circuit 201 includes a switching element and a freewheeling diode (not illustrated), converts the DC power supplied from power supply 100 into the AC power by switching of the switching element, and supplies the AC power to load 300. Although there are various specific circuit configurations of main conversion circuit 201, main conversion circuit 201 according to the present embodiment is a two-level three-phase full bridge circuit, and can be configured of six switching elements and six freewheeling diodes antiparallel to the respective switching elements. Semiconductor device 2 according to any one of the above-described first to third embodiments is applied to at least one of the switching elements and the freewheeling diodes of main conversion circuit 201. The six switching elements are connected in series by two switching elements to configure upper and lower arms, and each of the upper and lower arms configures each phase (U-phase, V-phase, W-phase) of a full bridge circuit. Output terminals of the upper and lower arms, that is, three output terminals of main conversion circuit 201 are connected to load 300.

Further, main conversion circuit 201 may be configured to include a drive circuit (not illustrated) to drive each of the switching elements, but the drive circuit may be built in semiconductor device 2, or may be configured to include the drive circuit separately from semiconductor device 2. The drive circuit generates a drive signal for driving each of the switching elements of main conversion circuit 201, and supplies the drive signal to a control electrode of each of the switching elements of main conversion circuit 201. Specifically, in accordance with the control signal from control circuit 203 described later, a drive signal for turning on the switching element and a drive signal for turning off the switching element are output to the control electrode of each of the switching elements. When the switching element is maintained in an ON state, the drive signal is a voltage signal equal to or higher than a threshold voltage of the switching element (ON signal), and when the switching element is maintained in an OFF state, the drive signal is a voltage signal equal to or lower than the threshold voltage of the switching element (OFF signal).

Control circuit 203 controls the switching elements of main conversion circuit 201 so that a desired power is supplied to load 300. Specifically, a time (ON time) during which each of the switching elements of main conversion circuit 201 is to be turned on is calculated on the basis of the power to be supplied to load 300. For example, main conversion circuit 201 can be controlled by PWM control that modulates the ON time of each of the switching elements in accordance with the voltage to be output. Then, a control command (control signal) is output to the drive circuit included in main conversion circuit 201 so that the ON signal is output to the switching element to be turned on, and the OFF signal is output to the switching element to be turned off at each time point. The drive circuit outputs the ON signal or the OFF signal as the drive signal to the control electrode of each of the switching elements in accordance with this control signal.

In the power conversion device according to the present embodiment, semiconductor device 2 according to any one of the first to third embodiments is applied as each of the switching elements and the freewheeling diodes of main conversion circuit 201, and service life diagnostic device 1 to diagnose the service life of semiconductor device 2 is mounted. Therefore, the remaining service life of semiconductor device 2 can be accurately diagnosed.

In the fourth embodiment, the example in which the present disclosure is applied to the two-level three-phase inverter has been described, but the present disclosure is not limited thereto, and can be applied to various power conversion devices. In the fourth embodiment, the two-level power conversion device is used, but a three-level or multi-level power conversion device may be used, or the present invention may be applied to a single-phase inverter in a case where a power is supplied to a single-phase load. In addition, when a power is supplied to a DC load or the like, the present invention can also be applied to a DC/DC converter or an AC/DC converter.

In addition, the power conversion device to which the present disclosure is applied is not limited to the case where the load described above is an electric motor, and can be used as, for example, a power supply device of an electric discharge machine, a laser beam machine, an induction heating cooker, or a non-contact power feeding system, and can also be used as a power conditioner of a solar power generation system, a power storage system, or the like.

It should be considered that the embodiments disclosed this time are examples and are not restrictive in all respects. The scope of the present disclosure is defined not by the description of the above embodiments but by the claims, and it is intended that all modifications within meaning and scope equivalent to the claims are included.

### REFERENCE SIGNS LIST

1, 1A: service life diagnostic device, 2: semiconductor device, 3, 3A: diagnostic processing unit, 4: display unit, 5: semiconductor element, 5a: collector electrode, 5b: emitter electrode, 6: collector main terminal, 7: gate terminal, 8: emitter main terminal, 9: emitter reference terminal, 10: collector-side main circuit connecting portion, 11: emitter-side main circuit connecting portion, 12, 12A: Vce amplifier, 13: Vee amplifier, 14, 15: reference value storage unit, 16, 17: temporal change extraction unit, 18: correlation value calculation unit, 19: storage unit, 20: temporal change calculation unit, 21: service life diagnostic unit, 22: metal plate, 23: connection portion, 24: path, 30: semiconductor module, 100: power supply, 200: power conversion device, 201: main conversion circuit, 203: control circuit, 300: load

1. A service life diagnostic device to diagnose a service life of a semiconductor device, the service life diagnostic device comprising:
a first voltage measuring circuit to measure a first voltage between a first terminal connected to a first electrode of a semiconductor element mounted on the semiconductor device and a second terminal connected to a second electrode of the semiconductor element;
a second voltage measuring circuit to measure a second voltage between the second terminal and a third terminal connected to the second electrode; and
a diagnostic circuit to diagnose the service life of the semiconductor device using a correlation value between a temporal change of the first voltage and a temporal change of the second voltage.

2. The service life diagnostic device according to claim 1, wherein
the temporal change of the first voltage is indicated by a first value obtained by subtracting a first constant from a magnification of a value of the first voltage with respect to a first reference value,
the temporal change of the second voltage is indicated by a second value obtained by subtracting a second constant from a magnification of a value of the second voltage with respect to a second reference value, and
the correlation value is a ratio between the first value and the second value.

3. The service life diagnostic device according to claim 2, wherein the first constant and the second constant are 1.

4. The service life diagnostic device according to claim 2, wherein the first constant and the second constant are 0.

5. The service life diagnostic device according to claim 2, wherein the first reference value and the second reference value are respectively a value of the first voltage and a value of the second voltage measured before start of use of the semiconductor device.

6. The service life diagnostic device according to claim 2, wherein the first reference value and the second reference value are respectively a value of the first voltage and a value of the second voltage measured after start of use of the semiconductor device.

7. A power conversion device, comprising:
the service life diagnostic device according to claim 1;
a main conversion circuit to convert an input power and output the input power, the main conversion circuit having a semiconductor device to be diagnosed by the service life diagnostic device;
a drive circuit to output a drive signal for driving the semiconductor device to the semiconductor device; and
a control circuit to output a control signal for controlling the drive circuit to the drive circuit.

8. The service life diagnostic device according to claim 3, wherein the first reference value and the second reference value are respectively a value of the first voltage and a value of the second voltage measured before start of use of the semiconductor device.

9. The service life diagnostic device according to claim 3, wherein the first reference value and the second reference value are respectively a value of the first voltage and a value of the second voltage measured after start of use of the semiconductor device.

10. The service life diagnostic device according to claim 4, wherein the first reference value and the second reference value are respectively a value of the first voltage and a value of the second voltage measured before start of use of the semiconductor device.

11. The service life diagnostic device according to claim 4, wherein the first reference value and the second reference value are respectively a value of the first voltage and a value of the second voltage measured after start of use of the semiconductor device.
